(19) United States
(12) Patent Application Publication
(10) Pub. No.: US 2026/0088809 A1
(43) Pub. Date: Mar. 26, 2026

(54) VOLTAGE BUFFER

(71) Applicant: SEMICONDUCTOR COMPONENTS INDUSTRIES, LLC, Scottsdale, AZ (US)

(72) Inventors: Shanil KURIACHAN, Wokingham (GB); Simon Charles DENNY, Reading (GB)

(73) Assignee: SEMICONDUCTOR COMPONENTS INDUSTRIES, LLC, Scottsdale, AZ (US)

(21) Appl. No.: 18/891,830

(22) Filed: Sep. 20, 2024

(51) Int. Cl. H03K 5/02; H03K 17/687; H03K 19/0175

(52) U.S. Cl. CPC H03K 5/02; H03K 17/6871; H03K 19/017509

(57) ABSTRACT

Systems, devices, and methods are provided for an improved voltage buffer. Improved voltage buffers may include an output circuit operating in a first voltage domain, and an input circuit operating in a second voltage domain and receiving a reference voltage and feedback signal. The second voltage domain may have a lower voltage than the first voltage domain. A bias circuit coupled between the input and output circuits may bias operation of the output circuit. An error signal from the input circuit may adjust the bias of the output circuit. A level shifting circuit may translate the adjusted bias signal from the second to the first voltage domain. The bias circuit may be controlled according to transistors having opposite V_{GS} temperature curves. Advantageously, a reduced portion of the voltage buffer may be exposed to over-voltage stress, and the voltage buffer may be more resistant to temperature-based fluctuations in output voltage.

### BACKGROUND

This application relates generally to voltage buffers and, more particularly, to Class AB voltage buffers.

Voltage buffers are important components in modern electronic design due to their ability to provide impedance matching, signal isolation, and voltage stability. By serving as intermediaries between different stages of a circuit, voltage buffers prevent signal degradation and ensure accurate voltage transmission, making them essential in applications such as analog-to-digital conversion, signal amplification, power supply regulation, and the like. Their versatility extends to a wide range of electronic systems, including image sensors, audio equipment, communication devices, and instrumentation.

Image sensors, for example CMOS image sensors, use voltage buffers to drive signals that control and bias pixels and are critical to the operation of the sensor. In some cases, such voltage buffers may be required to operate at and provide outputs at a higher or lower voltage than the transistors of the respective process technology are rated for. For example, transistors of a particular process technology may be rated to operate at 3 Volts maximum, and voltage buffers may temporarily provide control signals at voltages above this rating, for example at 4 Volts. Respective multiplexers that route the control signals, as well as the pixel transistors, may therefore be operated beyond a particular voltage rating, but are not operated continuously. The limited duty cycle therefore provides some protection to these components with respect to long-term reliability, yield, and the like.

The voltage buffers, in contrast, may operate continuously to provide such elevated voltage. To provide such elevated voltage signals, the voltage buffer operates in a higher voltage domain above the respective voltage rating of the transistors. This leads to increased power consumption due to continuous operation at a higher voltage.

Operating the transistors of the voltage buffer above the recommended voltage limit can also lead to degraded transistor performance through failure mechanisms such as time-dependent dielectric breakdown or hot carrier damage. Some failure mechanisms can lead to feedback cycles that rapidly increase resulting damage, such as burning holes in the oxide layer(s) of the transistors. It is also difficult to predict transistor lifetimes under such operating conditions, and difficult to model and analyze all transistors in such a design given the numerous modes of operation such as active mode, inactive, mode, switching mode, and the like.

It would therefore be desirable to provide improved voltage buffers devices and methods having lower power, increased reliability, and reduced design risk, among other features.

### BRIEF DESCRIPTION OF DRAWING FIGURES

FIG. 1A is a schematic diagram showing a first exemplary voltage buffer, according to various embodiments.

FIG. 1B is a schematic diagram of an NMOS biasing circuit for the first exemplary voltage buffer, according to various embodiments.

FIG. 1C is a schematic diagram of a PMOS biasing circuit for the first exemplary voltage buffer, according to various embodiments.

FIG. 2A is a schematic diagram showing a second exemplary voltage buffer, according to various embodiments.

FIG. 2B is a schematic diagram of an NMOS biasing circuit for the second exemplary voltage buffer, according to various embodiments.

FIG. 2C is a schematic diagram of a PMOS biasing circuit for the second exemplary voltage buffer, according to various embodiments.

FIG. 3 illustrates a simulated voltages of various circuit components compared to temperature, according to various embodiments.

FIG. 4A is a partial schematic diagram of a third exemplary voltage buffer, according to various embodiments.

FIG. 4B is a schematic diagram of a PMOS biasing circuit for the third exemplary voltage buffer, according to various embodiments.

### BRIEF SUMMARY

Various embodiments relate to systems, devices, and methods for voltage buffers.

According to various embodiments, a voltage buffer may include an input circuit operable in a second voltage domain and configured to receive an input voltage reference and a feedback signal, where the input circuit is configured to generate an error signal based on the feedback signal and the input voltage reference; an output circuit operable in a first voltage domain and may include an output node, where the output circuit is controllable to provide an output voltage at the output node, and where the first voltage domain is a higher voltage than the second voltage domain; a feedback circuit coupled with the output circuit and the input circuit, where the feedback circuit is configured to generate the feedback signal based on the output voltage; a bias circuit coupled with the input circuit, where the bias circuit is configured to provide a bias signal configured to operate the output circuit in Class AB mode and where the error signal adjusts the bias signal provided by the bias circuit; and a level shifting circuit operable in the first voltage domain and coupled with the bias circuit and the output circuit, where the level shifting circuit is configured to translate the adjusted bias signal from the second voltage domain to the first voltage domain, and where the output circuit is controllable by the translated adjusted bias signal.

According to various embodiments, a voltage buffer may include a feedback circuit; an error amplifier including a first input, a second input, and an error output, where the first input is coupled with a voltage reference, the second input is coupled with the feedback circuit, and where the error amplifier is further coupled to a second voltage supply; an output circuit that may include a sourcing transistor coupled in series with a sinking transistor and a first voltage supply, where: the sourcing transistor and sinking transistor are coupled at a first output node; the first output node is coupled with the feedback circuit; and a first voltage provided by the first voltage supply is greater than a second voltage provided by the second voltage supply. The buffer also includes a level shifting circuit that may include a third input and a second output, where: the level shifting circuit is coupled with the first voltage supply; the second output is coupled with the sourcing transistor; and the level shifting circuit is configured to receive a voltage signal on the third input, increase a voltage level of the received voltage signal, and provide the increased voltage signal on the second output. The buffer also includes a bias circuit coupled with the error output and the third input, where the bias circuit is configured to control an operating point of the sourcing transistor and an operating point of the sinking transistor.

According to various embodiments, a voltage buffer may include an input circuit configured to receive an input voltage reference, receive a feedback signal, and generate an error signal based on the feedback signal and the input voltage reference; an output circuit that may include an output node, where the output circuit is controllable to provide an output voltage at the output node; a feedback circuit coupled with the output circuit and the input circuit, where the feedback circuit is configured to generate the feedback signal based on the output voltage; and a bias circuit coupled with the input circuit and the output circuit, where: the bias circuit may include a first NMOS transistor coupled in parallel with a first PMOS transistor, where a gate terminal of the NMOS transistor is coupled with an N-bias circuit and a gate terminal of the PMOS transistor is coupled with a P-bias circuit; the P-bias circuit may include a diode-connected second PMOS transistor coupled in series with a diode-connected third PMOS transistor; the second PMOS transistor has a source-to-gate voltage temperature curve having a positive slope; and the third PMOS transistor has a source-to-gate voltage temperature curve having a negative slope.

These and other examples are described in increasing detail below.

### DETAILED DESCRIPTION

The following detailed description is intended to provide several examples that will illustrate the broader concepts that are set forth herein, but it is not intended to limit the invention or the application and uses of the invention. Furthermore, there is no intention to be bound by any theory presented in the preceding background or the following detailed description.

According to various embodiments, voltage buffer devices and methods are used to receive an input voltage signal, for example a reference voltage, and drive an output voltage accordingly. The voltage buffer may be configured as a Class AB voltage buffer, for example operating a push-pull output circuit in Class AB mode. Various embodiments may include configurations having a combination of transistors with a positive temperature slope and a negative temperature slop to provide bias voltages having improved operating point stability with respect to temperature.

Various embodiments may include other improved circuits, for example operating the input portion of the voltage buffer in a lower voltage domain and operating the output portion of the voltage buffer in a higher voltage domain, without a significant increase in circuit size. In some embodiments, the higher voltage domain may provide an operating voltage and an output voltage higher than the rated voltage of the transistors and/or process technology used to implement the voltage buffer, while the input voltage and lower voltage domain may be at a voltage lower than the rated voltage. The voltage buffer may include a level shifter configured to translate bias and/or error signals between the lower voltage domain and the higher voltage domain. For example, the input voltage reference may be 2 Volts (V), the rated voltage may be 3 V, and the output voltage may be 4 V.

Voltage buffers according to the various embodiments described herein may be used in any suitable application, especially those requiring a higher buffered voltage than what the transistors are rated for, such as in image sensor drivers and voltage buffers, power management circuits, low-dropout regulators (LDO), and/or the like. For further example, voltage buffers according to the various embodiments described herein may be used for lower voltage LDOs, for example using a level shifting circuit to generate a negative output voltage for control, biasing, or the like.

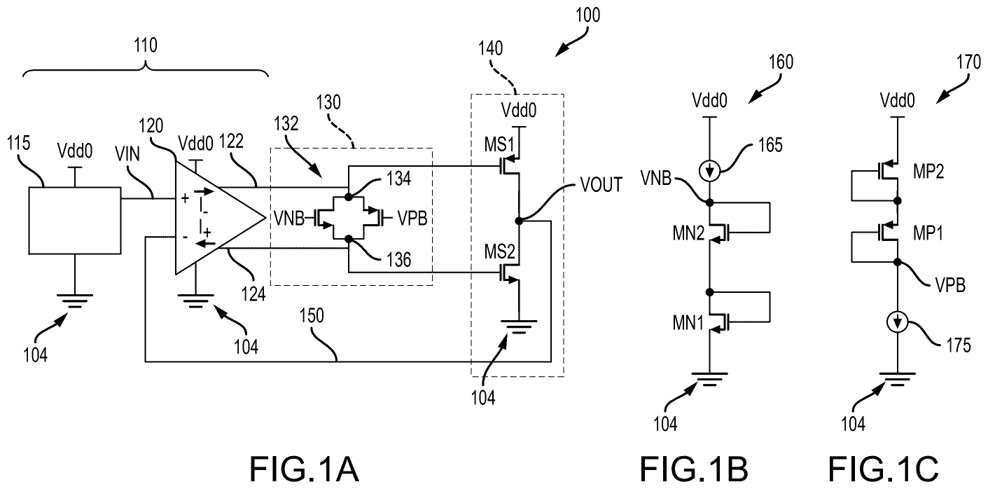

FIG. 1A illustrates a first exemplary embodiment of a voltage buffer 100. The voltage buffer 100 may include an input circuit 110 configured to generate or otherwise receive an input voltage to buffer, and an output circuit 140 configured to provide the buffered voltage to a load (not shown) connected to output node VOUT. The voltage buffer 100 may isolate the generated or otherwise received input voltage from the output circuit 140 and any circuit connected to the output circuit 140, and/or may maintain a voltage level at the output node VOUT. The output voltage at the output node VOUT may be maintained at the same level as the input voltage from the input circuit 110, at an amplified level based on the input voltage, and/or at a reduced level based on the input voltage.

The output circuit 140 may be configured to provide sufficient current to the load to maintain a consistent voltage at the output node VOUT. In some embodiments, the output circuit 140 may include a push-pull configuration of transistors that supply current to (“source”) and/or absorb current from (“sink”) the load. The push-pull configuration of transistors may include a sourcing transistor MS1 coupled in series with a sinking transistor MS2. The sourcing transistor MS1 may be coupled between a voltage supply Vdd0 and the output node VOUT, and the sinking transistor MS2 may be coupled between the output node VOUT and a common voltage node 104.

The push-pull configuration of transistors may comprise MOSFET transistors. In some embodiments, the sourcing transistor MS1 may be a PMOS transistor having its source terminal coupled with the voltage supply Vdd0 and its drain terminal coupled with the output node VOUT. The sinking transistor MS2 may be an NMOS transistor having its source terminal coupled with the common voltage node 104 and its drain terminal coupled with output node VOUT.

The voltage supply Vdd0 may be an operating voltage reference for the circuits of the voltage buffer 100. The voltage supply Vdd0 may be determined according to the particular semiconductor manufacturing processes, design rules, expected input voltage, requirements for driving the load, and the like. In some embodiments, the voltage supply Vdd0 may be on the order of 1 V, 10V, 100 V, or the like. In some embodiments, the voltage supply Vdd0 may be between 1 V and 10V, for example between 2V and 8V, for example about 5V. The common voltage node 104 may be a common reference voltage for the circuit, for example ground, a negative voltage reference, or the like.

Still referring to FIG. 1A, a bias circuit 130 may provide a stable operating point for the voltage buffer 100. In some embodiments, the bias circuit 130 may be designed to operate the output circuit 140 in a Class AB mode, for example by controlling the operating points (also referred to as biasing points) of each transistor of the output circuit 140. The bias circuit 130 may be referred to as the buffer bias circuit 130. The bias circuit 130 may receive one or more input signals, for example one or more currents, from the input circuit 110. The bias circuit 130 may provide one or more bias signals, for example voltage levels, to control the transistors of the output circuit 140. In some embodiments, the bias circuit 130 may influence or otherwise control the output circuit 140 based on one or more error signals from the input circuit 110 that relate to the input and/or output voltage levels.

The bias circuit 130 may include any suitable bias circuit, for example a preset voltage bias, a voltage divider network, a series connected diode arrangement, or the like. In some embodiments, the bias circuit 130 may be configured as a floating battery 132, which may also be referred to as a floating current mirror, Monticelli bias scheme, or Monticelli bias circuit. For example, the floating battery 132 may include a PMOS transistor coupled in parallel with an NMOS transistor, with the drain terminal of the NMOS transistor coupled to the source terminal of the PMOS transistor at a first bias node 134, and the source terminal of the NMOS transistor coupled to the drain terminal of the PMOS transistor at a second bias node 136.

In some embodiments, the first bias node 134 may be coupled with the gate terminal of the sourcing transistor MS1 and the second bias node 136 may be coupled with the gate terminal of the sinking transistor MS2. The first bias node 134 may also be coupled with the input circuit 110 to receive a first error signal 122, and the second bias node 136 may also be coupled with the input circuit 110 to receive a second error signal 124. While the bias circuit 130 provides the correct biasing of the output circuit 140 to operate the output circuit 140 in Class AB amplifier mode, the received error signal(s) from the input circuit 110 may adjust the provided biasing to cause the sourcing transistor MS1 or sinking transistor MS2 to source or sink more current, respectively, depending on the determined error.

Referring to FIGS. 1A-1C, in some embodiments, the gate of the NMOS transistor of the floating battery 132 may have its gate terminal biased by a N-bias circuit 160, and the gate of the PMOS transistor of the floating battery 132 may have its gate terminal biased by a P-bias circuit 170. The N-bias circuit 160 may be any suitable circuit to bias the gate of the NMOS transistor of the floating battery 132, and the P-bias circuit 170 may be any suitable circuit to bias the gate of the PMOS transistor of the floating battery 132. The N-bias circuit 160 may include a N-bias current source 165 coupled in series with a first N-bias transistor MN1 and a second N-bias transistor MN2. In some embodiments, the first N-bias transistor MN1 and second N-bias transistor MN2 are NMOS transistors.

Referring to FIG. 1B, the N-bias current source 165 may be coupled between the voltage supply Vdd0 and the drain terminal of the second N-bias transistor MN2, the source terminal of the second N-bias transistor MN2 may be coupled with the drain terminal of the first N-bias transistor MN1, and the source terminal of the first N-bias transistor MN1 may be coupled with the common voltage node 104. The first N-bias transistor MN1 and second N-bias transistor MN2 may be configured as diode-coupled transistors, having their respective drain terminals coupled with their respective gate terminals.

The N-bias circuit 160 may generate an N-bias voltage reference at a VN_BIAS output node where the N-bias current source 165 is coupled with the drain terminal of the second N-bias transistor MN2. The VN_BIAS node may be referred to herein as the VNB node. The gate of the NMOS transistor of the floating battery 132 may be coupled to the VNB node.

Referring to FIG. 1C, in some embodiments, the P-bias circuit 170 may include a P-bias current source 175 coupled in series with a first P-bias transistor MP1 and a second P-bias transistor MP2. In some embodiments, the first P-bias transistor MP1 and second P-bias transistor MP2 are PMOS transistors. The P-bias current source 175 may be coupled between the common voltage node 104 and the drain terminal of the first P-bias transistor MP1, the source terminal of the first P-bias transistor MP1 may be coupled with the drain terminal of the second P-bias transistor MP2, and the source terminal of the second P-bias transistor MP2 may be coupled with the voltage supply Vdd0.

The first P-bias transistor MP1 and second P-bias transistor MP2 may be configured as diode-connected transistors, having their respective drain terminals coupled with their respective gate terminals. The P-bias circuit 170 may generate a P-bias voltage reference at a VP_BIAS output node where the P-bias current source 175 is coupled with the drain terminal of the first P-bias transistor MP1. The VP_BIAS node may be referred to herein as the VPB node. The gate of the PMOS transistor of the floating battery 132 may be coupled to the VPB node.

In some embodiments, the N-bias current source 165 and P-bias current source 175 may be matched. In some embodiments, the N-bias current source 165 and P-bias current source 175 may be cascaded current sources so that even if the voltage varies with temperature and/or process parameters, the current remains approximately fixed. The various PMOS and NMOS transistors of the bias circuit 130, output circuit 140, N-bias current source 165, and P-bias current source 175 may be any suitable size, for example any suitable width-length (W/L) ratios, based on desired operating characteristics, process parameters, design requirements, and the like.

Referring again to FIG. 1A, the input circuit 110 may include any suitable circuitry to generate or otherwise receive an input voltage and determining a difference between the input voltage and the desired corresponding output voltage. The determined difference may be referred to as the error between the input voltage and the output voltage. In some embodiments, the input circuit 110 includes a voltage reference circuit 115 coupled with an error amplifier 120.

The voltage reference circuit 115 may include any suitable circuit to generate a predetermined voltage reference. In some embodiments, the voltage reference circuit 115 may include a bandgap reference circuit. In some embodiments the voltage reference level may be equal to or less than the voltage supply Vdd0. The voltage reference circuit 115 may output the voltage reference as a reference voltage signal VIN.

The error amplifier 120 may receive the reference voltage signal VIN from the voltage reference circuit 115 on a first input terminal, for example on a positive input terminal of the error amplifier 120. In some embodiments, the error amplifier 120 may further receive a feedback signal from a feedback circuit 150 on a second input terminal. The feedback circuit 150 may be configured to provide an indication of the output voltage at the output node VOUT. In some embodiments, the feedback circuit 150 may include a direct or indirect connection of the output node VOUT to a negative input of the error amplifier 120.

The error amplifier 120 may be configured to determine one or more error signals based on the received reference voltage signal VIN and the feedback signal. In some embodiments, the one or more error signals may be determined based on a difference between the reference voltage signal VIN and the feedback signal. In some embodiments, the error amplifier 120 may output a first error signal 122 and a second error signal 124. As described above, the first error signal 122 and second error signal 124 may be coupled with the first bias node 134 and second bias node 136 of the bias circuit 130, respectively. The first error signal 122 and second error signal 124 may be current-based signals, voltage-based signals, and/or the like.

In some embodiments, the error amplifier 120 may generate the first error signal 122 and second error signal 124 as current-based signals based on the difference between the reference and feedback input signals. For example, the error amplifier 120 may output a first current I₋ on the first error signal 122 and a second current I₊ on the second error signal 124. If the received reference voltage signal VIN increases, the first current I₋ will decrease, which will decrease the current in the floating battery 132. Reduction in the current causes a reduction of V_{SG} of the PMOS transistor of the floating battery 132. Because the voltage at the VPB node remains constant, the gate voltage of the PMOS transistor cannot be increased, and the source voltage of the PMOS transistor of the floating battery 132 must decrease, which causes the voltage at the output node VOUT to increase due to the decrease in voltage at the first bias node 134.

Similarly, if the feedback signal increases, the second current I₊ will decrease, which will decrease the current in the floating battery 132. Reduction in the current causes a reduction of V_{GS} of the NMOS transistor of the floating battery 132. Because the voltage at the VNB node remains constant, the gate voltage of the NMOS transistor cannot be reduced, and the source voltage of the NMOS transistor of the floating battery 132 must increase, which causes the voltage at the output node VOUT to decrease due to the increase in voltage at the second bias node 136. Connecting the feedback signal to the negative input of the error amplifier 120 provides negative feedback.

The voltage reference circuit 115 and the error amplifier 120 may also be suitably coupled with the voltage supply Vdd0 and the common voltage node 104. In some embodiments, for example when used to drive voltage levels for use in readout circuitry of a CMOS image sensor, the desired output voltage at the output node VOUT may be approximately 4 V, the voltage reference circuit 115 may generate a reference voltage signal VIN to be the same as the desired output voltage, for example approximately 4 V, and the voltage supply Vdd0 may be about 5 V.

Accordingly, a voltage buffer 100 according to the first exemplary embodiment may maintain an approximately consistent output voltage, for example 4 V, at the output node VOUT based on the reference voltage signal VIN generated by the voltage reference circuit 115. As the output voltage fluctuates due to the load and/or other conditions such as temperature-based component variations, the error amplifier 120 generates appropriate error signal(s) which are used by the bias circuit 130 to control the operation of the output circuit 140. For example, the output circuit 140 may be controlled to source additional current through the sourcing transistor MS1 if the output voltage is below the reference voltage signal VIN and/or to sink additional current through the sinking transistor MS2 if the output voltage is above the reference voltage signal VIN.

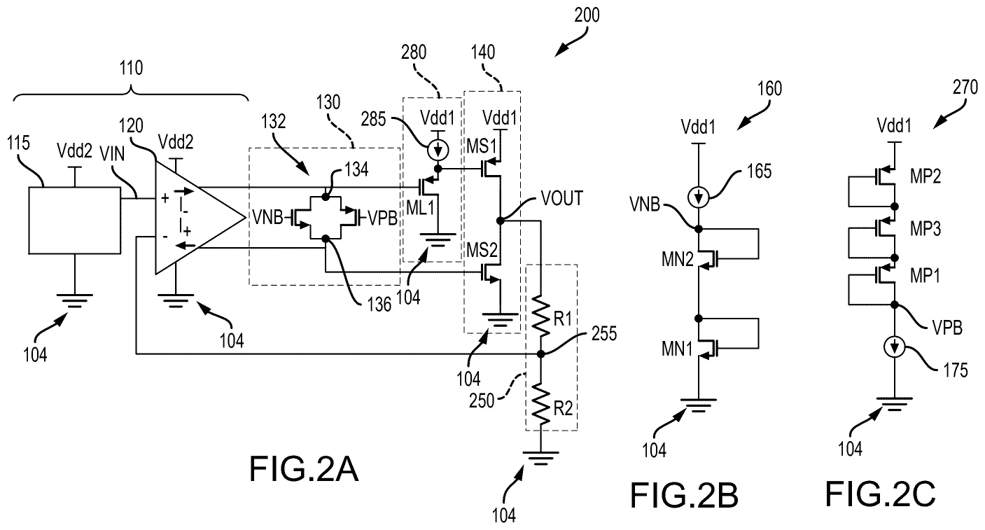

FIG. 2A illustrates a second exemplary embodiment of a voltage buffer 200. In some such embodiments, the voltage buffer 200 may include the same arrangement of input circuit 110 and bias circuit 130 as described above. For example, in some embodiments, the input circuit 110 may include the voltage reference circuit 115 and error amplifier 120, and the bias circuit 130 may include a floating battery 132 and/or other suitable bias circuitry. Additionally, the voltage buffer 200 may include the same output circuit 140 as described above, and may include a feedback circuit 250 coupled between the output circuit 140 and the error amplifier 120.

In some embodiments, the voltage buffer 200 may include a level shifting circuit 280 coupled between the bias circuit 130 and the output circuit 140. The level shifting circuit 280 may comprise any suitable circuit configured to translate (e.g., suitably increase or decrease) the voltage level of the adjusted bias signal provided by first bias node 134 to the output circuit 140. For example, the level shifting circuit 280 may allow the output circuit 140 to operate in a first voltage domain while the input circuit 110 and/or floating battery 132 operate in a second voltage domain by increasing the level of the signal provided by the first bias node 134 by an appropriate amount. The level shifting circuit 280 may operate in the first voltage domain. In some embodiments, the first voltage domain may include a first voltage supply Vdd1 and the second voltage domain may include a second voltage supply Vdd2. The first voltage supply Vdd1 may provide a higher voltage level than that provided by the second voltage supply Vdd2.

In some embodiments, the level shifting circuit 280 may include a transistor configured as a source follower coupled in series with a current source between the first voltage supply Vdd1 and the common voltage node 104. For example, the level shifting circuit 280 may include a PMOS source follower transistor ML1 having its gate terminal coupled with the first bias node 134, its source terminal coupled with a level shifter current source 285 and the gate terminal of the sourcing transistor MS1, and its drain terminal coupled with the common voltage node 104. The level shifter current source 285 may be coupled between the first voltage supply Vdd1 and the source follower transistor ML1. The second bias node 136 of the bias circuit 130 may be coupled with the gate terminal of the sinking transistor MS2. In some embodiments, the level shifter current source 285 may be matched with the N-bias current source 165 and/or P-bias current source 175, for example each providing the same impedance, current, and/or the like.

The various transistors of the voltage buffer 200, for example the transistors of the input circuit 110 (including the voltage reference circuit 115 and the error amplifier 120), bias circuit 130, output circuit 140, and/or the like, may have a rated operational voltage limit. The rated operational voltage limit may be a recommended voltage limit, for example recommended by the respective foundry. The rated operational voltage limit may relate to transistor performance, reliability, expected lifetime of the transistors and/or electrical traces, and/or the like, and may depend on the particular semiconductor manufacturing process used to manufacture the voltage buffer. For example, the voltage buffer 200 may be a semiconductor-based device including CMOS transistors that have a rated operational voltage limit of about 1.0 V to about 5.0 V, for example about 3.0 V.

In some embodiments, the voltage buffer 200 may be configured to provide an output voltage VOUT that is higher than the rated operational voltage limit. The first voltage supply Vdd1 may also be greater than the rated operational voltage limit, for example to allow the output circuit 140 to maintain the desired output voltage VOUT higher than the rated operational voltage limit. In some embodiments, through use of the level shifting circuit 280, the second voltage supply Vdd2 may be less than or equal to the rated operational voltage limit. In some embodiments, the circuits and devices operating in the first voltage domain may be operated with voltage shielding to protect other devices and circuits from exposure to the higher first voltage supply Vdd1.

For example, the voltage buffer 200 may be implemented with a CMOS process having a rated operational voltage limit for transistors of about 3.0 V. The voltage buffer 200 may be configured provide an output voltage VOUT of about 4.0 V, the first voltage supply Vdd1 may be about 5.0 V, the second voltage supply Vdd2 may be about 2.8 V, and the reference voltage signal VIN may be about 2.0 V. In some embodiments, the second voltage supply Vdd2 may be set at or just under, for example about 5%, 10%, 15%, or 20% less than, the rated operational voltage limit.

The voltage buffer 200 may include a feedback circuit 250 coupled with the output voltage VOUT and the error amplifier 120, for example to a negative input of the error amplifier 120. The feedback circuit 250 may be configured to provide, to the error amplifier 120, an indication of the level of the output voltage VOUT. In some embodiments, the feedback circuit 250 may convert the level of the output voltage VOUT to the reference voltage signal VIN level. For example, if the output voltage VOUT is configured to be 4.0 V and the reference voltage signal VIN is configured to be 2.0 V, the feedback circuit 250 may divide the output voltage VOUT level in half.

More generally, the feedback circuit 250 may divide the output voltage VOUT by some amount depending on the chosen ratio of the output voltage VOUT to the reference voltage signal VIN. In some embodiments, the feedback circuit 250 may include a voltage divider, for example implemented using series-connected resistors, with the feedback signal selected from among the connection points of the two or more resistors. The feedback circuit 250 may include a first resistor R1 coupled between the output voltage VOUT and a second resistor R2, and the second resistor R2 may be coupled between the first resistor R1 and the common voltage node 104. The input of the error amplifier 120 may be coupled to the node between the first resistor R1 and the second resistor R2. In the example given above, the first resistor R1 and second resistor R2 may be selected to have the same resistance to divide the output voltage VOUT level in half.

Advantageously, operating the output circuit 140 at the first voltage supply Vdd1 and the voltage reference circuit 115 and error amplifier 120 at the second voltage supply Vdd2 provides a voltage buffer having reduced power consumption. In some embodiments, the total current budget for a voltage buffer 200 may be partitioned between the input circuit 110 and the output circuit 140. For example, the output circuit 140, possibly along with the level shifting circuit 280, may be allocated one third of the current budget, and the remainder of the voltage buffer 200—primarily the input circuit 110—may be allocated two thirds of the current budget. According to the above example of a 5.0 V first voltage supply Vdd1 and 2.8 V second voltage supply Vdd2, and with the current partition as described just above, the second exemplary voltage buffer 200 uses approximately 30% less power compared to a first exemplary voltage buffer 100 operating entirely at a 5.0 V voltage supply Vdd0.

In addition to the power reduction described above, a voltage buffer 200 according to the second exemplary embodiment has reduced risk of being impacted by insufficient design and engineering. For example, a voltage buffer 200 according to the second exemplary embodiment requires fewer additional protection circuits to protect against over-voltage stress. The yield of producing such devices may therefore be increased, as well as the reliability thereof.

Referring to FIG. 2B, in some embodiments, the VNB node may be driven by an N-bias circuit 160 as described above with respect to FIG. 1B, wherein the voltage supply is the first voltage supply Vdd1. Referring to FIG. 2C, in some embodiments, the VPB node may be driven by a second exemplary embodiment of the P-bias circuit 270. The second exemplary embodiment of the P-bias circuit 270 may include an additional transistor compared to the first exemplary embodiment of the P-bias circuit 170 described above with respect to FIG. 1C, for example to account for the additional source follower transistor ML1.

In some embodiments, the P-bias circuit 270 may include the P-bias current source 175 coupled in series with the first P-bias transistor MP1, the second P-bias transistor MP2, and a third P-bias transistor MP3. In some embodiments, the first P-bias transistor MP1, second P-bias transistor MP2, and third P-bias transistor MP3 are PMOS transistors. The first P-bias transistor MP1, second P-bias transistor MP2, and third P-bias transistor MP3 may each be configured as diode-connected transistors. Other arrangements and number of transistors may be used, depending for example on chosen transistor parameters (e.g., Width/Length (W/L) ratio) or the like.

The first P-bias transistor MP1, second P-bias transistor MP2, and third P-bias transistor MP3 may be coupled in series in any suitable order between the first voltage supply Vdd1 and the P-bias current source 175. In some embodiments, the P-bias current source 175 may be coupled between the common voltage node 104 and the drain terminal of the first P-bias transistor MP1, the source terminal of the first P-bias transistor MP1 may be coupled with the drain terminal of the third P-bias transistor MP3, the source terminal of the third P-bias transistor MP3 may be coupled with the drain of the second P-bias transistor MP2, and the source terminal of the second P-bias transistor MP2 may be coupled with the first voltage supply Vdd1. The P-bias current source 175 may generate a P-bias voltage reference at the VPB output node where the P-bias current source 175 is coupled with the series-coupled transistors MP1, MP2, MP3.

The P-bias voltage reference at the VPB node is based on the sum of the gate-to-source voltages (V_{GS}) of the first P-bias transistor MP1, second P-bias transistor MP2, and third P-bias transistor MP3. In some embodiments, the third P-bias transistor MP3 may be configured, for example designed and manufactured, having a longer channel than the first P-bias transistor MP1 and second P-bias transistor MP2. More generally, the P-bias circuit 270 and/or N-bias circuit 160 may include suitable combinations of shorter-channel and longer-channel transistors.

The gate-to-source voltage (V_{GS}) of a transistor is based on the threshold voltage (V_{TH}) and carrier mobility (μ), among various process and other parameters. In general, V_{GS} is positive for an NMOS transistor and negative for a PMOS transistor. The source-to-gate voltage (V_{SG}) is therefore positive for a PMOS transistor. The following discussion will refer to absolute values so as to apply to both NMOS and PMOS transistors.

As temperature increases, |V_{TH}| decreases and contributes to a negative temperature slope for |V_{GS}|, that is it causes |V_{GS}| to decrease with increasing temperature. Further, as temperature increases, μ decreases and contributes to a positive temperature slope for |V_{GS}|, that is it causes |V_{GS}| to increase with increasing temperature. Increasing the channel length will increase the |V_{GS}| slope due to u, that is it will increase the effect of u on the temperature slope of |V_{GS}|.

In some embodiments, the first P-bias transistor MP1 and the second P-bias transistor MP2 may be configured with a sufficiently short channel to provide an overall negative temperature slope for V_{SG}, and the third P-bias transistor MP3 may be configured with a sufficiently long channel to provide an overall positive temperature slope for V_{SG}. The competing temperature slopes may partially or completely cancel each other, and may reduce the process, voltage, and temperature variation of the summed V_{SG} and therefore the variation of the P-bias voltage reference at the VPB node.

More generally, the P-bias circuit 270 and/or N-bias circuit 160 may be configured to have one or more transistors having a negative |V_{GS}| temperature slope and one or more transistors having a positive |V_{GS}| temperature slope, where the combined negative and positive temperature slopes at least partially cancel each other and reduce variation of the respective bias voltages. This can increase the likelihood of maintaining proper quiescent conditions and biasing of the various components of the voltage buffer 200, which may further increase yield.

The source follower transistor ML1 may be configured with a longer channel and a positive |V_{GS}| temperature slope. In some embodiments, the source follower transistor ML1 and the third P-bias transistor MP3 may be matched, for example having the same channel type, length, process parameters, W/L ratio, and/or the like. The longer channel source follower transistor ML1 can help reduce the bias voltage variation with temperature and therefore helps improve biasing and yield.

In some embodiments, the first P-bias transistor MP1 may be matched with the PMOS transistor of the floating battery 132. In some embodiments, the sourcing transistor MS1 may be matched to the second P-bias transistor MP2 with a gain, for example having some multiple of the W/L ratio of the second P-bias transistor MP2. For example, the sourcing transistor MS1 may have the same length but a multiple of width compared to the second P-bias transistor MP2.

Similarly, the first N-bias transistor MN1 and second N-bias transistor MN2 may be matched with the NMOS transistor of the floating battery 132 and the sinking transistor MS2. Both the sourcing transistor MS1 and sinking transistor MS2 may have the same gain as compared to the respective short-channel NMOS and PMOS transistors of the N-bias circuit 160 and P-bias circuit 270.

By way of non-limiting example, the first P-bias transistor MP1, second P-bias transistor MP2, and PMOS transistor of the floating battery 132 may be configured to have a W/L ratio of about 50, and the third P-bias transistor MP3 and the source follower transistor ML1 may be configured to have a W/L ratio of about 0.25. The first P-bias transistor MP1, second P-bias transistor MP2, and PMOS transistor of the floating battery 132 may have the same first channel width and length, and the third P-bias transistor MP3 and the source follower transistor ML1 may have the same second channel width and length. The sourcing transistor MS1 may have the first channel length and a multiple of the first channel width, for example having a W/L ratio of about 600, which is a gain factor of about 12 in the example above.

By way of non-limiting example, the NMOS transistor of the floating battery 132 and the NMOS transistors of the N-bias circuit 160 may be configured to have a W/L ratio of about 32. The NMOS transistor of the floating battery 132 and the NMOS transistors of the N-bias circuit 160 may have the same third channel width and length, and the sinking transistor MS2 may have the third channel length and a multiple of the third channel width, for example having a W/L ratio of about 240, which is a gain factor of about 12 in the example above. In some embodiments, the third channel length may be configured to be the same or about the same as the first channel length of the short-channel PMOS transistors.

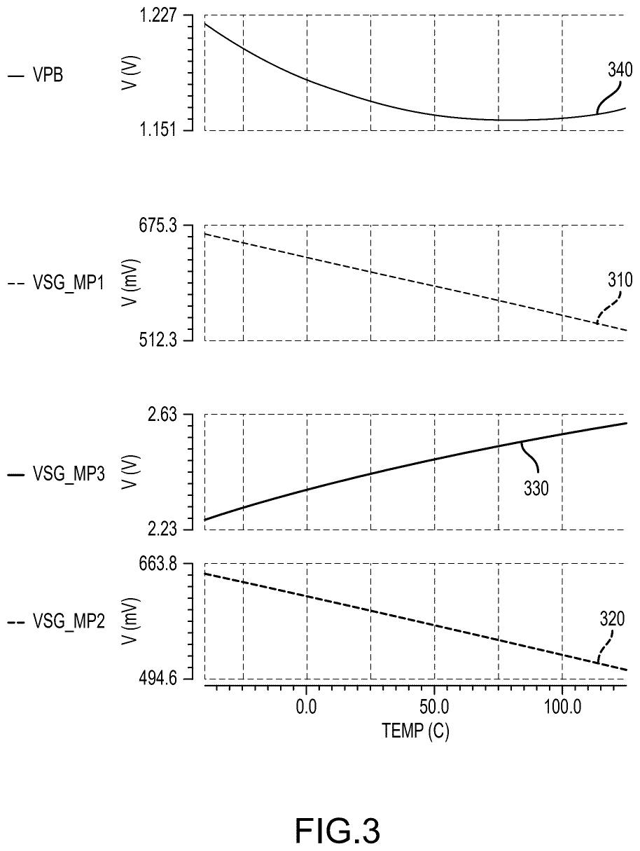

FIG. 3 shows simulation results for an exemplary voltage buffer according to the second exemplary voltage buffer 200 and having the W/L ratios exemplified above. Specifically, the P-bias circuit 270 was simulated over a range of temperatures from −40 Celsius to +125 Celsius. The V_{SG} of each of the first P-bias transistor MP1, second P-bias transistor MP2, and third P-bias transistor MP3 were plotted, along with the combined P-bias voltage reference at the VPB node. Note that the source-to-gate voltage is shown in the graphs due to simulation of PMOS transistors.

As shown, the temperature curve 310 for the first P-bias transistor MP1 and the temperature curve 320 for the second P-bias transistor MP2 have a negative slope, with the V_{GS} for each varying from about 660 mV at the coldest temperature to about 525 mV at the warmest temperature. In other words, the V_{GS} varies about 135 mV for each of the exemplary short channel transistors in the P-bias circuit 270. If three such transistors were used in the P-bias circuit 270, then the expected overall variation in voltage at the VPB node would be about three times that value, or about 405 mV.

As shown in FIG. 3, using the third P-bias transistor MP3 (and similarly the source follower transistor ML1, not shown) having a longer channel and a resulting positive slope for the |V_{GS}| curve 330 (i.e., V_{GS} for PMOS), the overall voltage at the VPB node experiences less variation. For example, the Vos of the third P-bias transistor MP3 varies from about 2.25 V at the coldest temperature to about 2.6 V at the warmest temperature. The temperature curve 340 for the voltage at the VPB node is obtained by summing the three temperature curves 310, 320, 330 for the PMOS transistors of the P-bias circuit 270. The summation of the three simulated V_{GS} curves 310, 320, 330 results in a total swing in the voltage at the VPB node of about 1.22 V at the coldest temperature to a minimum of about 1.16 V at about 80 Celsius. Thus, according to the example above, the P-bias circuit 270 having transistors with opposite temperature curves results in a maximum VPB node voltage variation of about 63.5 mV, or about 6.5 times less voltage variation compared to using all short channel transistors.

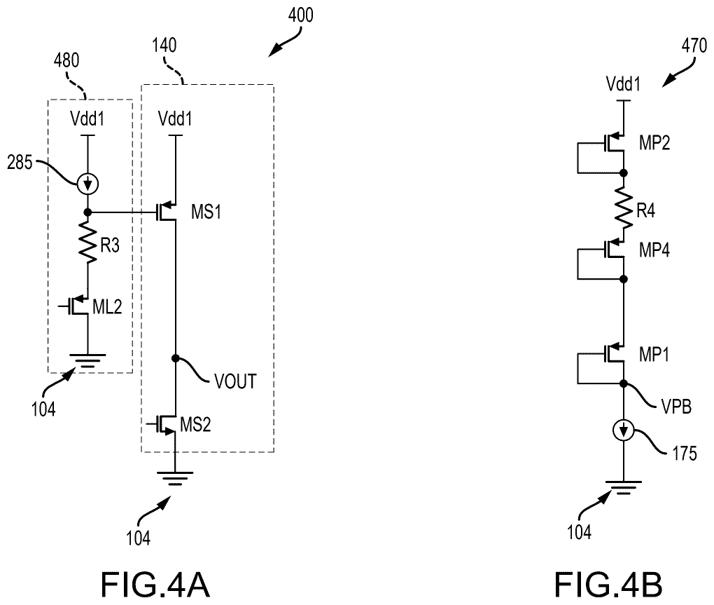

FIG. 4A shows a partial schematic of a third exemplary embodiment of a voltage buffer 400. The third exemplary embodiment of the voltage buffer 400 may be the same as the second exemplary embodiment of the voltage buffer 200, but including resistors in a second exemplary embodiment of a level shifting circuit 480 and in a third exemplary embodiment of a P-bias circuit 470. In some embodiments, the long channel transistors in the level shifting circuit 480 and P-bias circuit 470 may be replaced with short channel transistors.

For example, the level shifting circuit 480 may include a third resistor R3 coupled in series between the level shifter current source 285 and a second source follower transistor ML2. The second source follower transistor ML2 may be a short channel transistor, for example matched to the PMOS transistor of the battery 132, the first P-bias transistor MP1, and/or the second P-bias transistor MP2. Similarly, the P-bias circuit 470 may include a fourth resistor R4 coupled in series with the first P-bias transistor MP1, second P-bias transistor MP2, and a fourth P-bias transistor MP4. The fourth P-bias transistor MP4 may be a short channel transistor, for example matched as the second source follower transistor ML2 may be matched. In some embodiments, the third resistor R3 and the fourth resistor R4 may have the same resistance.

In some embodiments, the level shifter current source 285 and the P-bias current source 175 may be derived from a bandgap reference (V_{BG}), such that the current provided by the level shifter current source 285 and P-bias current source 175 is V_{BG}/R, where R is the resistance of the third resistor R3 and fourth resistor R4. Therefore, the voltage across third resistor R3 and fourth resistor R4 is

$$\frac{{V}_{BG}}{R} \times R = {V}_{BG} .$$

The bandgap voltage may have low temperature dependency, and may therefore have low variation with respect to temperature. In some embodiments, use of resistors third resistor R3 and fourth resistor R4 instead of or in addition to long channel transistors may require increased area to implement.

Various embodiments therefore provide improved voltage buffers requiring less power, having improved response to temperature and other process variations, and having more robust and less risky implementations. Power may be reduced by moving the input stages of the voltage buffer to a lower voltage domain and using a source follower to translate the bias signals from the lower voltage domain to a higher voltage domain. The design risk may be reduced by operating more transistors within the foundry prescribed voltage range, while still providing output voltages that are above the prescribed voltage range. Further, manufacturing yield may be improved by providing temperature compensated bias voltages, which may reliably operate the output circuit in Class AB mode. Other embodiments may provide additional benefits and features, as desired.

The various functions shown and described in the various circuits of the several exemplary embodiments herein may be distributed in various suitable configurations amongst the various components of the voltage buffer and/or circuits and components to which the voltage buffers are connected, and different embodiments may organize the various functions and circuits in any number of suitable configurations.

References to transistors herein may refer to any suitable type of transistor technology, such as bipolar junction transistors (BJTs), field-effect transistors (FETs) such as metal-oxide-semiconductor field-effect transistors (MOSFETs), and the like. References may be made to a doping type of the transistors, such as a P-channel MOSFET (PMOS), N-channel MOSFET (NMOS), and the like. It will be recognized that the embodiments described herein may include alternatives having reversed and/or reconfigured selection of transistor types. Further, references to signals herein refer to electrical signals such as a voltage level, unless specified otherwise.

References to a “node” refer to an electrical node unless otherwise specified. Electrical nodes may exist physically at one or more locations, for example as part of a conductive trace that extends from or between one or more electrical devices. Terms such as coupled, connected, or the like refer to electrical coupling unless stated otherwise and also refer to direct and/or indirect coupling, connection, or the like unless stated otherwise.

The general concepts set forth herein may be adapted to any number of alternate but equivalent embodiments. The term “exemplary” is used herein to represent one example, instance or illustration that may have any number of alternates. Any implementation described herein as “exemplary” is not necessarily to be construed as preferred or advantageous over other implementations, nor is it necessarily intended as a model that must be duplicated in other implementations. While several exemplary embodiments have been presented in the foregoing detailed description, it should be appreciated that a vast number of alternate but equivalent variations exist, and the examples presented herein are not intended to limit the scope, applicability, or configuration of the invention in any way. To the contrary, various changes may be made in the function and arrangement of elements described without departing from the scope of the claims and their legal equivalents.

What is claimed is:

1. A voltage buffer, comprising:
an output circuit operable in a first voltage domain and comprising an output node, wherein the output circuit is controllable to provide an output voltage at the output node;
an input circuit operable in a second voltage domain and configured to receive an input voltage reference and a feedback signal, wherein the input circuit is configured to generate an error signal based on the feedback signal and the input voltage reference, and wherein the first voltage domain is a higher voltage than the second voltage domain;
a feedback circuit coupled with the output circuit and the input circuit, wherein the feedback circuit is configured to generate the feedback signal based on the output voltage;
a buffer bias circuit coupled with the input circuit, wherein the buffer bias circuit is configured to provide a bias signal and wherein the error signal adjusts the bias signal provided by the buffer bias circuit; and
a level shifting circuit operable in the first voltage domain and coupled with the buffer bias circuit and the output circuit, wherein the level shifting circuit is configured to translate the adjusted bias signal from the second voltage domain to the first voltage domain, and wherein the output circuit is controllable by the translated adjusted bias signal.

2. The voltage buffer of claim 1, wherein:
each of the input circuit, output circuit, buffer bias circuit, and level shifting circuit comprise one or more transistors;
the second voltage domain comprises a second operating voltage less than or equal to a rated operational voltage limit of the one or more transistors; and
the first voltage domain comprises a first operating voltage greater than the rated operational voltage limit of the one or more transistors.

3. The voltage buffer of claim 2, wherein the first operating voltage is about 5.0 Volts and the second operating voltage is about 2.8 Volts.

4. The voltage buffer of claim 2, wherein the input voltage reference is about 2.0 Volts and the output voltage is about 4.0 Volts.

5. The voltage buffer of claim 3, wherein the input voltage reference is about 2.0 Volts and the output voltage is about 4.0 Volts.

6. The voltage buffer of claim 1, wherein the buffer bias circuit comprises a floating current mirror, the floating current mirror comprising:
a first NMOS transistor coupled in parallel with a first PMOS transistor, wherein a gate terminal of the NMOS transistor is coupled with an output of an N-bias circuit and a gate terminal of the PMOS transistor is coupled with an output of a P-bias circuit.

7. The voltage buffer of claim 6, wherein the P-bias circuit comprises a current source, a second PMOS transistor, and a third PMOS transistor, wherein:
the second PMOS transistor and the third PMOS transistor are configured as diode-connected transistors;
the second PMOS transistor and the third PMOS transistor are coupled in series with a first operating voltage;
the current source is coupled, at the output of the P-bias circuit, in series with the second PMOS transistor and the third PMOS transistor;
the second PMOS transistor has a source-to-gate voltage temperature curve having a positive slope; and
the third PMOS transistor has a source-to-gate voltage temperature curve having a negative slope.

8. The voltage buffer of claim 7, wherein the level shifting circuit comprises a source follower transistor matched to the second PMOS transistor.

9. A voltage buffer, comprising:
a feedback circuit;
an error amplifier comprising a first input, a second input, and an error output, wherein the first input is coupled with a voltage reference, the second input is coupled with the feedback circuit, and wherein the error amplifier is further coupled to a second voltage supply;
an output circuit comprising a sourcing transistor coupled in series with a sinking transistor and a first voltage supply, wherein:
the sourcing transistor and sinking transistor are coupled at a first output node;
the first output node is coupled with the feedback circuit; and
a first voltage provided by the first voltage supply is greater than a second voltage provided by the second voltage supply;
a level shifting circuit comprising a third input and a second output, wherein:
the level shifting circuit is coupled with the first voltage supply;
the second output is coupled with the sourcing transistor; and
the level shifting circuit is configured to receive a voltage signal on the third input, increase a voltage level of the received voltage signal, and provide the increased voltage signal on the second output; and
a buffer bias circuit coupled with the error output and the third input, wherein the buffer bias circuit is configured to control an operating point of the sourcing transistor and an operating point of the sinking transistor.

10. The voltage buffer of claim 9, wherein:
the error amplifier comprises one or more transistors;
the second voltage is less than or equal to a rated operational voltage limit of the one or more transistors of the error amplifier; and
the first voltage is greater than the rated operational voltage limit.

11. The voltage buffer of claim 10, wherein the first voltage is about 5.0 Volts and the second voltage is about 2.8 Volts.

12. The voltage buffer of claim 9, wherein the voltage reference is about 2.0 Volts and an output voltage from the first output node is about 4.0 Volts.

13. The voltage buffer of claim 9, wherein the feedback circuit is configured to:
receive an output voltage from the first output node;
reduce a voltage level of the received output voltage; and
provide the reduced output voltage to the second input of the error amplifier.

14. The voltage buffer of claim 9, wherein the buffer bias circuit comprises a floating current mirror having a first NMOS transistor coupled in parallel with a first PMOS transistor, wherein a gate terminal of the NMOS transistor is coupled with an output of an N-bias circuit and a gate terminal of the PMOS transistor is coupled with an output of a P-bias circuit.

15. The voltage buffer of claim 14, wherein the P-bias circuit comprises a current source, a second PMOS transistor, and a third PMOS transistor, wherein:
the second PMOS transistor and the third PMOS transistor are coupled in series with the first voltage supply;
the current source is coupled, at the output of the P-bias circuit, in series with the second PMOS transistor and the third PMOS transistor;
the second PMOS transistor has a source-to-gate voltage temperature curve having a positive slope; and
the third PMOS transistor has a source-to-gate voltage temperature curve having a negative slope.

16. The voltage buffer of claim 15, wherein the level shifting circuit comprises a source follower transistor matched to the second PMOS transistor.

17. A voltage buffer, comprising:
an input circuit configured to receive an input voltage reference, receive a feedback signal, and generate an error signal based on the feedback signal and the input voltage reference;
an output circuit comprising an output node, wherein the output circuit is controllable to provide an output voltage at the output node;
a feedback circuit coupled with the output circuit and the input circuit, wherein the feedback circuit is configured to generate the feedback signal based on the output voltage; and
a buffer bias circuit coupled with the input circuit and the output circuit, wherein:
the buffer bias circuit comprises a first NMOS transistor coupled in parallel with a first PMOS transistor, wherein a gate terminal of the NMOS transistor is coupled with an N-bias circuit and a gate terminal of the PMOS transistor is coupled with a P-bias circuit;
the P-bias circuit comprises a diode-connected second PMOS transistor coupled in series with a diode-connected third PMOS transistor;
the second PMOS transistor has a source-to-gate voltage temperature curve having a positive slope; and
the third PMOS transistor has a source-to-gate voltage temperature curve having a negative slope.

18. The voltage buffer of claim 17, further comprising a level shifting circuit, wherein:
the buffer bias circuit is coupled to the output circuit through the level shifting circuit; and
the level shifting circuit comprises a source follower transistor matched to the second PMOS transistor.

19. The voltage buffer of claim 18, wherein:
the input circuit is operable in a second voltage domain; and
the level shifting circuit and the output circuit are operable in a first voltage domain, wherein the first voltage domain comprises a first voltage level and the second voltage domain comprises a second voltage level, wherein the second voltage level is less than the first voltage level.

20. The voltage buffer of claim 19, wherein:
the input circuit comprises one or more transistors;
the second voltage level is less than or equal to a rated operational voltage limit of the one or more transistors of the input circuit; and
the first voltage level is greater than the rated operational voltage limit.
